(19) United States
(12) Patent Application Publication
(10) Pub. No.: US 2003/0124797 A1
(43) Pub. Date: Jul. 3, 2003

(54) Method for fabricating a semiconductor device

(76) Inventors: Jin Woong Kim, Chungchongbuk-Do (KR); Dong Won Han, Seoul (KR)

Correspondence Address: BIRCH STEWART KOLASCH & BIRCH, PO BOX 747, FALLS CHURCH, VA, 22040-0747, US

(21) Appl. No.: 10/315,979

(22) Filed: Dec. 11, 2002

(30) Foreign Application Priority Data
Dec. 19, 2001 (KR) 2001-0081200

(51) Int. Cl. H01L 21/8234; H01L 21/8244; H01L 21/8242; H01L 21/20

(52) U.S. Cl. 438/253; 438/396

(57) ABSTRACT

A method for fabricating a semiconductor device is disclosed, which prevents the problem generated from a gap-fill failure from occurring when dividing a lower electrode by a CMP process in a capacitor having the dimensions of a tall height and a narrow width, thereby improving the capacitance. The method includes the steps of sequentially forming a first insulating interlayer, a barrier insulating layer, and a second insulating interlayer on a substrate, etching the second insulating interlayer at a constant interval to expose the barrier insulating layer, forming a semiconductor layer on an entire surface of the substrate including the second insulating interlayer, performing an annealing process to the semiconductor layer, thereby forming a hemi-spherical semiconductor layer, depositing an inorganic insulating layer on the entire surface of the substrate including the hemi-spherical semiconductor layer, hardening an upper part of the inorganic insulating layer on the hemi-spherical semiconductor layer by an annealing process, dividing a lower electrode of a capacitor by polishing the hardened inorganic insulating layer and the hemi-spherical semiconductor layer to expose the upper part of the second insulating interlayer, removing the inorganic insulating layer by a subsequent process after the polishing process, and forming an upper electrode and a dielectric layer on the lower electrode.

This application claims the benefit of the Korean Application No. P2001-81200 filed on Dec. 19, 2001, which is hereby incorporated by reference.

### BACKGROUND OF THE INVENTION

1. Field of the Invention

The present invention relates to a semiconductor device, and more particularly, to a method for fabricating a semiconductor device of improved capacitance that can prevent a problem generated from a gap-fill failure when dividing a lower electrode by a chemical-mechanical polishing (CMP) process from occurring in a capacitor having the dimensions of a tall height and a narrow width.

2. Discussion of the Related Art

A method for fabricating a related art semiconductor device will be described with reference to the accompanying drawings.

FIG. 1A to FIG. 1E illustrate cross sectional views of fabricating process steps of the related art semiconductor device.

As shown in FIG. 1A, a first insulating interlayer 11 is formed on a silicon substrate (not shown), and then a barrier insulating layer 12 of silicon nitride is deposited on the first insulating interlayer 11.

Next, a second insulating interlayer 13 is deposited on the barrier insulating layer 12. A photoresist (not shown) is deposited on the second insulating interlayer 13, which is then selectively patterned at a constant interval by exposing and developing processes.

Subsequently, the second insulating interlayer 13 is anisotropic etched by utilizing the patterned photoresist as a mask, thereby patterning the second insulating interlayer 13 with constant intervals.

At this time, the barrier insulating layer 12 is served as an etch stopping layer during the etching of the second insulating interlayer 13.

The second insulating interlayer 13 is formed of tetra-ethyl ortho silicate (TEOS) material.

As shown in FIG. 1B, a polysilicon layer 14 is formed on surfaces of the second insulating interlayer 13 patterned constant intervals and on the barrier insulating layer 12.

As shown in FIG. 1C, the polysilicon layer 14 is annealed and patterned so that the polysilicon layer 14 is formed as a hemi-spherical surface area enhanced silicon (SAES) layer 15.

The SAES layer 15 is formed to increase the surface area of a lower electrode of a capacitor, thereby improving capacitance.

As shown in FIG. 1D, an undoped silicate glass (USG) layer 16 is formed on the entire surface of the silicon substrate.

At this time, the gap between the patterned second insulating interlayers on the SAES layer 15 is not perfectly filled with the USG layer 16 due to the SAES layer 15, thereby forming a void.

As shown in FIG. 1E, the USG layer 16 and the SAES layer 15 are selectively removed by a CMP process to expose an upper part of the second insulating interlayer 13, thereby dividing the SAES layer 15.

Accordingly, the lower electrode 15a of the capacitor is divided.

However, a slurry is formed in the gap of the lower electrode 15a in the capacitor due to the void during the CMP process. Furthermore, a failure may occur during the wet etch process due to the separation of the SAES layer 15.

Although not shown, a dielectric layer and an upper electrode of the capacitor are sequentially formed on the lower electrode 15a of the capacitor, thereby completing the capacitor.

However, the related art semiconductor device has the following problems.

If the SAES layer is thickened to improve capacitance, a gap-fill failure such as the void occurs during the depositing of the USG layer, so that a slurry is introduced into the gap of the lower electrode in the capacitor during the CMP process.

### SUMMARY OF THE INVENTION

Accordingly, the present invention is directed to a semiconductor device that substantially obviates one or more problems due to limitations and disadvantages of the related art.

Thus, an object of the present invention is to provide a method for fabricating a semiconductor device that can improve capacitance and prevent problems generated by the occurrence of a gap-fill failure.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the present invention, as embodied and broadly described herein, a method for fabricating a semiconductor device includes the steps of sequentially forming a first insulating interlayer, a barrier insulating layer, and a second insulating interlayer on a substrate, etching the second insulating interlayer at a constant interval to expose the barrier insulating layer, forming a semiconductor layer on the entire surface of the substrate, including the second insulating interlayer, performing an annealing process to the semiconductor layer, thereby forming a hemi-spherical semiconductor layer, depositing an inorganic insulating layer on the entire surface of the substrate including the hemi-spherical semiconductor layer, hardening an upper part of the inorganic insulating layer on the hemispherical semiconductor layer by an annealing process, dividing a lower electrode of a capacitor by polishing the hardened inorganic insulating layer and the hemi-spherical semiconductor layer to expose the upper part of the second insulating interlayer, removing the inorganic insulating layer by a subsequent process after the polishing process, and forming an upper electrode and a dielectric layer on the lower electrode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together, with the description, serve to explain the principle of the invention. In the drawings:

FIG. 1a to FIG. 1e are cross sectional views illustrating fabricating process steps of a related art semiconductor device; and

FIG. 2a to FIG. 2f are cross sectional views illustrating fabricating process steps of a semiconductor device according to the present invention.

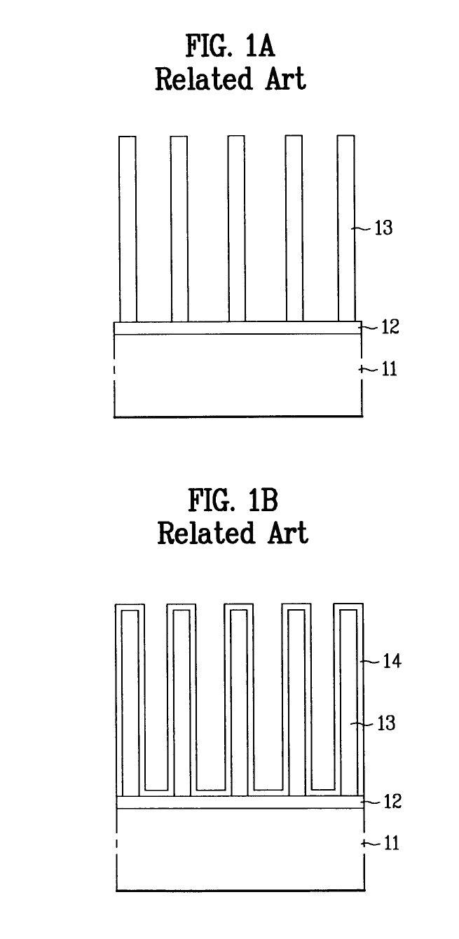

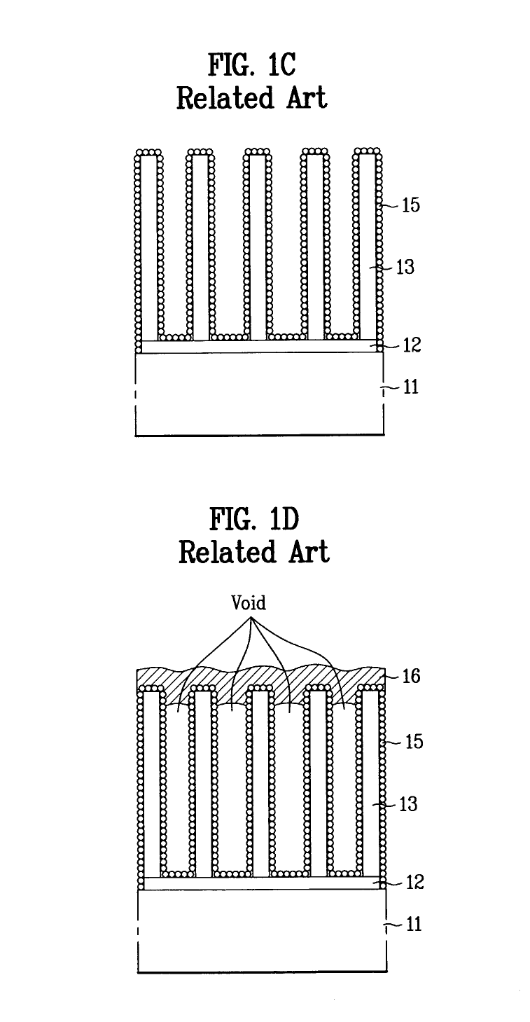

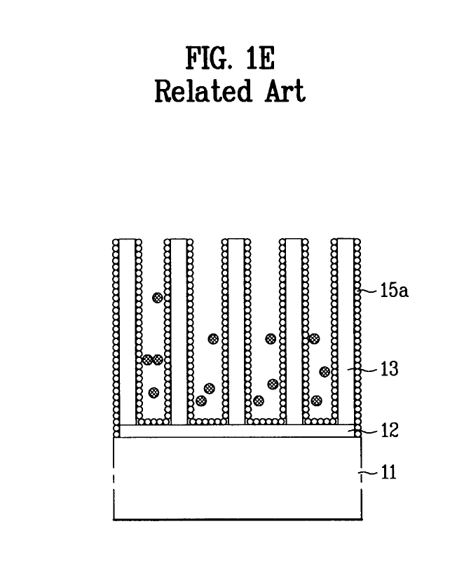

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

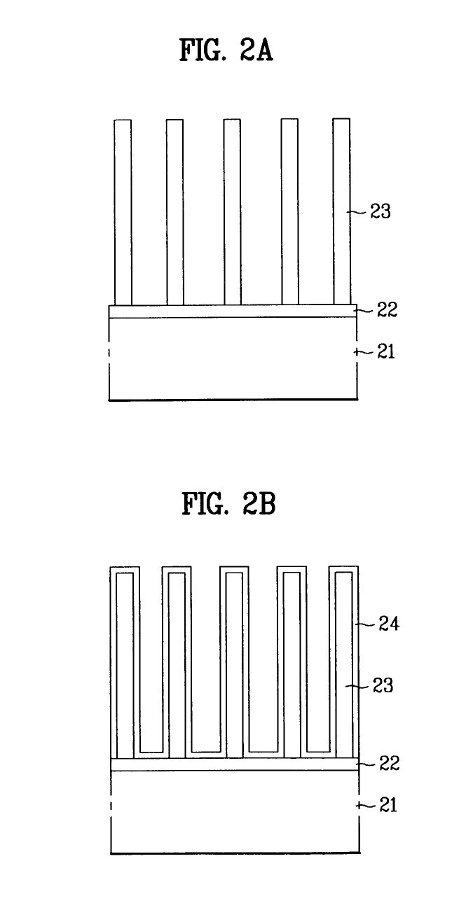

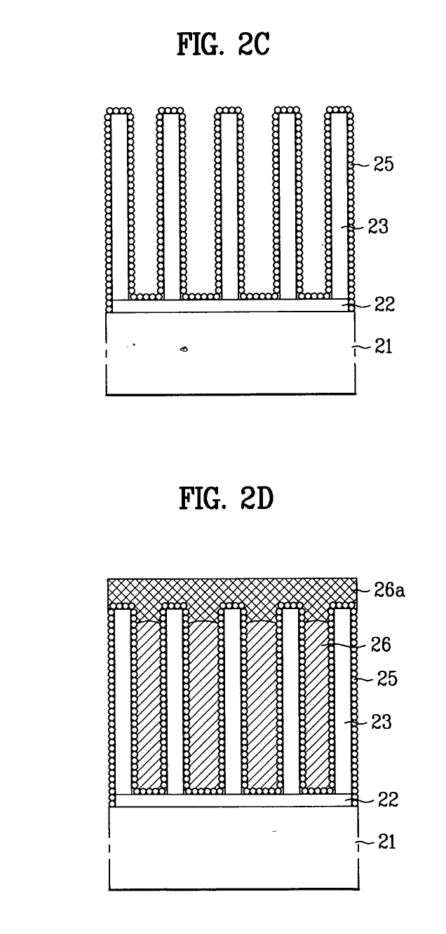

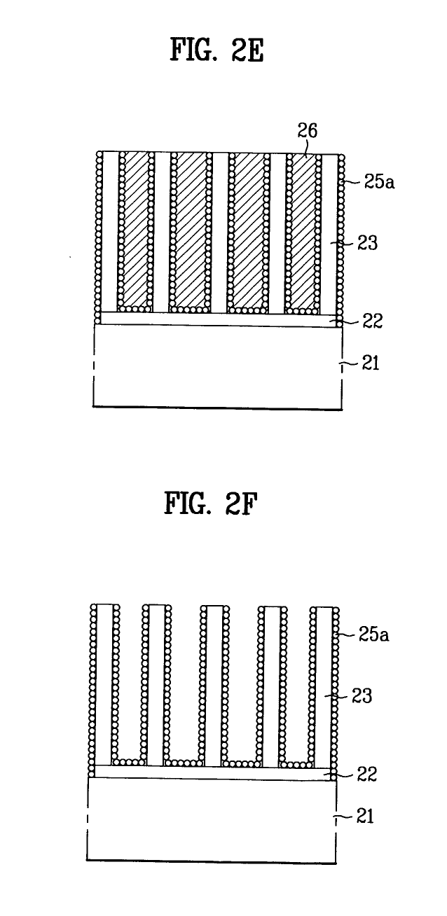

FIG. 2a to FIG. 2f are cross sectional views illustrating fabricating process steps of a semiconductor device according to the present invention.

First, the semiconductor device according to the present invention will be schematically described.

In the present invention, a lower electrode of a capacitor is divided by a chemical mechanical polishing (CMP) process during the forming the capacitor (third gate: TG).

Especially, a gap between second insulating interlayers on a SAES layer is perfectly filled by depositing an inorganic insulating layer such as FOₓ having a good flux. At this time, the SAES layer is the lower electrode of the capacitor. Then, an upper part of the inorganic insulating layer is hardened, and a CMP process is performed thereon, thereby dividing the lower electrode of the capacitor.

The semiconductor device according to the present invention will be now described with reference to the accompanying drawings.

As shown in FIG. 2A, a first insulating interlayer 21 is formed on a silicon substrate (not shown), and then a barrier insulating layer 22 of a silicon nitride is formed on the first insulating interlayer 21.

Next, a second insulating interlayer 23 is deposited on the barrier insulating layer 22. A photoresist (not shown) is deposited on the second insulating interlayer 22, and then is selectively patterned at a constant interval by exposing and developing processes.

Subsequently, the second insulating interlayer 23 is anisotropic etched by using the patterned photoresist as a mask, thereby patterning the second insulating interlayer 23 at a constant interval.

At this time, the barrier insulating layer 22 serves as an etch stopping layer during the etching of the second insulating interlayer 23.

The second insulating interlayer 23 is a material formed of tetra ethyl ortho silicate (TEOS).

As shown in FIG. 2B, a polysilicon layer 24 is formed on the surfaces of the second insulating interlayer 23, patterned at constant intervals and on the barrier insulating layer 22.

As shown in FIG. 2C, the polysilicon layer 24 is annealed and patterned so that the polysilicon layer 24 is patterned as a hemi-spherical surface area enhanced silicon (SAES) layer 25.

The SAES layer 25 is formed to increase the surface area of a lower electrode in a capacitor, thereby improving capacitance.

As shown in FIG. 2D, an inorganic insulating layer 26 such as FOₓ (flowable oxide) is deposited on the entire surface of the silicon substrate including the SAES layer 25 to fill the gaps between the patterned second insulating interlayers and on the SAES layer 25.

In the related art, an undoped silicate glass (USG) layer is formed on the entire surface of the silicon substrate to fill the gap between the patterned second insulating interlayers and on the SAES layer 25. However, with the integration of devices, there is a problem in that the gap is not perfectly filled with the USG layer. Accordingly, an inorganic insulating layer such as FOₓ having a good flux, is used in the present invention.

As shown in FIG. 20, the inorganic insulating layer 26 is annealed, thereby forming a hardened inorganic insulating layer 26a.

However, the hardened inorganic insulating layer 26a is not formed at a lower part of the gap between the patterned second insulating interlayers on the SAES layer 25. That is, the hardened inorganic insulating layer 26a is formed at the upper part of the patterned second insulating interlayers on the SAES layer 25, and is thinned by hardening.

The hardened inorganic insulating layer 26a is formed to prevent the inorganic insulating layer 26 from being damaged during the CMP process.

Even though the FOₓ has a good gap-fill characteristic, the FOₓ is a porous material having a high etch rate, so that the FOₓ may be removed during the CMP process, thereby generating contamination due to slurry formation. Accordingly, the inorganic insulating layer is hardened in the present invention.

At this time, the inorganic insulating layer 26 has a low dielectric rate of between 2.7 and 3.0, and the hardened inorganic insulating layer 26a has a dielectric rate of between 4.0 and 4.2.

As shown above, if the inorganic insulating layer of the low dielectric rate is hardened, the low dielectric characteristic is lost, and the inorganic insulating layer is thinned. Therefore, the characteristics of the inorganic insulating layer becomes similar to a general oxide layer.

In the above, the inorganic insulating layer 26 can be hardened not only by an annealing process but also by a plasma process (N₂, O₂, NH₃ or Ar), an e-beam process, an annealing process in a furnace (O₂, N₂, N₂O or H₂), and a rapid thermal process (RTP).

As shown in FIG. 2E, the hardened inorganic insulating layer 26a and the upper part of the SAES layer 25 are etched by the CMP process to expose the second insulating interlayer 23.

As a result, the SAES layer 25 is divided, thereby dividing the lower electrode 25a of the capacitor.

As shown in FIG. 2F, since the inorganic insulating layer 26 that is not hardened has a high etch rate, it is removed during cleaning after the CMP process, so that other, later processes are not required.

The gap between the patterned second insulating interlayers on the SAES layer 25 is filled with the inorganic insulating layer 25 even though the SAES layer 25 is thick, thereby preventing the gap-fill failure from occurring.

Although not shown, a dielectric layer and an upper electrode are sequentially formed on the lower electrode 25a of the capacitor, thereby completely forming the capacitor.

The semiconductor device according to the present invention has the following advantages.

First, the inorganic insulating layer such as FOₓ having a good gap-fill characteristic, is used in the present invention, so that it is possible to prevent a gap-fill failure generated by depositing the USG layer, from occurring.

Furthermore, the gap between the patterned second insulating interlayers on the SAES layer can be filled with the inorganic insulating layer such as FOₓ even though the SAES layer becomes thick, thereby avoiding the formation of a void. Therefore, improved capacitance can be easily obtained.

Next, the inorganic insulating layer is hardened by the annealing process, and then the lower electrode of the capacitor is divided. That is, a slurry does not come into the lower electrode of the capacitor during the CMP process.

Finally, the inorganic insulating layer can be removed between the lower electrodes without wet etch that is performed to remove the USG layer in the related art, thereby simplifying the fabricating process steps. Also, it is possible to prevent the SAES layer from being separated during the wet etch.

It will be apparent to those skilled in the art than various modifications and variations can be made in the present invention. Thus, it is intended that the present invention covers the modifications and variations of this invention provided they come within the scope of the appended claims and their equivalents.

What is claimed is:

1. A method for fabricating a semiconductor device comprising the steps of:
sequentially forming a first insulating interlayer, a barrier insulating layer, and a second insulating interlayer on a substrate;
etching the second insulating interlayer at constant intervals to expose the barrier insulating layer;
forming a semiconductor layer on an entire surface of the substrate including the second insulating interlayer;
performing an annealing process to the semiconductor layer, thereby forming a hemi-spherical semiconductor layer;
depositing an inorganic insulating layer on the entire surface of the substrate including the hemi-spherical semiconductor layer;
hardening an upper part of the inorganic insulating layer on the hemi-spherical semiconductor layer by an annealing process;
dividing a lower electrode of a capacitor by polishing the hardened inorganic insulating layer and the hemi spherical semiconductor layer to expose the upper part of the second insulating interlayer;
removing the inorganic insulating layer by a subsequent process after the polishing process; and
forming an upper electrode and a dielectric layer on the lower electrode.

2. The method as claimed in claim 1, wherein the inorganic insulating layer is formed of FOₓ (flowable oxide).

3. The method as claimed in claim 1, wherein the inorganic insulating layer has a dielectric rate of between 2.7 and 3.0.

4. The method as claimed in claim 1, wherein the hardened inorganic insulating layer has a dielectric rate of between 4.0 and 4.2.

5. The method as claimed in claim 1, wherein the polishing process is a chemical-mechanical polishing (CMP) process.

6. The method as claimed in claim 1, wherein the inorganic insulating layer may be hardened by an annealing process, a plasma process using N₂, O₂, NH₃ or Ar, an e-beam process, a thermal process in a furnace using O₂, N₂, N₂O, H₂ or NH₃ or a RTP process.

7. The method as claimed in claim 1, wherein the barrier insulating layer is formed of silicon nitride.

8. The method as claimed in claim 1, wherein the semiconductor layer is formed of a polysilicon layer.

9. The method as claimed in claim 1, wherein the hemispherical semiconductor layer is a surface area enhanced silicon (SAES) layer formed by the annealing process.

10. The method as claimed in claim 1, wherein the second insulating interlayer is a material formed of tetraethyl ortho silicate (TEOS).
